(19) United States
(12) Patent Application Publication
(10) Pub. No.: US 2004/0031904 A1
(43) Pub. Date: Feb. 19, 2004

(54) Apparatus of linear staggered sensors

(75) Inventor: Shih-Huang Chen, Hsin-Chu City (TW)

Correspondence Address: LOWE HAUPTMAN GILMAN & BERNER, LLP, Suite 310, 1700 Diagonal Road, Alexandria, VA, 22314, US

(73) Assignee: UMAX DATA SYSTEMS INC.

(21) Appl. No.: 10/216,853

(22) Filed: Aug. 13, 2002

(51) Int. Cl. H01L 27/00

(52) U.S. Cl. 250/208.1

(57) ABSTRACT

An apparatus of linear staggered sensors. The scan comprises a first sensor and a second sensor. The first sensor is laterally offset from the second sensor, the sensors comprises a plurality of charge coupled devices, wherein the each of charge coupled device comprises a photosensitive zones and a non-photosensitive zones, the charge coupled devices of the sensors are linear arrangement; and the first sensor is abutting with the second sensor, wherein the first sensor is abutting place with the second sensor is the non-photosensitive zones.

### BACKGROUND OF THE INVENTION

1. Field of the Invention

The present invention relates to an apparatus for increasing the image space frequency, and more particularly relates to an apparatus of linear staggered sensors.

2. Description of the Prior Art

People have already recognized that charge coupled devices (CCDs) or CMOS (complementary metal-oxide semiconductor) devices may be advantageously utilized as photosensitive detector elements for any image capture apparatus, such as a scanner. It has been shown that many mutually independent CCDs can be formed on a single chip of semiconductor material, such as silicon. Nevertheless, for high line scanning resolution capability is demanded of some image capture apparatuses, integrated CCD detector arrays involve optically interlacing or stitching the photocell elements within several rows of a two-dimensional integrated array to perform the scanning.

As illustrated in FIG. 1A, a light-sensitive device 10 consists of a charge-coupled device (CCD) 12. The CCD 12 has three scanning lines, one is red color scanning line (R), another is green color scanning line (G), and the other is blue color scanning line (B). Each of the three scanning lines consists of a plurality of crystals 14, and the three scanning lines are used for scanning and transforming an image into three electrical signals representative of the red portion, green portion, and blue portion of the image, respectively. As illustrated in FIG. 1B, it shows a plane view of the conventional square crystal structure (x=y=1 pixel width), wherein x is the vertical dimension and y is the lateral dimension. The conventional CCD scanning apparatus consists of a plurality of square crystals, and the feature of the square crystal may be a square, a polygon or an ellipticity-shaped. Actually, the square crystal is a square structure in the ratio between vertical dimension x and lateral dimension y, and the vertical dimension of the square crystal structure is equal to the lateral dimension of the square crystal structure approximately 1 pixel width.

Typically, a sensor array comprises multitudes of equidistantly spaced and mutually independent CCD detectors in each of successive rows. More than enough resolution elements or pixels to provide a high-resolution definition of a scan line are imaged onto a single row of detectors. However, a limited number of CCD detectors that may be formed in any one row of the sensor array are insufficient to obtain high-resolution input scanning through the use of just one row of photocells. To perform high resolution input scanning despite the characteristically low line resolution capabilities of the sensor array, the photosensitive zones of the photocells are laterally staggered or offset form one another in the line scanning direction so that individual pixels from each scan line are separately imaged onto respective ones of the photocells in one or another of the rows for the sensor array.

For example, a staggered sensor array comprises at least two sensor rows: first sensor row and second sensor row arranged in an offset form. Each sensor row comprises multitudes of aligned photocells. When all of the pixels of each scan line are detected with a predetermined number of frames, each of the photocells responds to spatially predetermine one of the pixels of each scan line. Shown in FIG. 2A, number 5 represents a first series of video signals P1, P2 responded by the photocells (the number is 8, for example) in the first sensor row. Number 10 represents a second series of video signals P1′, P2′ responded by the photocells (the number is also 8) in the first sensor row. In FIG. 2B, number 15 represents a series of clock pulses applied to the staggered sensor array to shift or read out the data samples generated by the photocells of the first and second sensor rows. Multiple clock pulses may be supplied per frame to serially read out the data samples from the photocells in successive rows of the staggered sensor array. For a high resolution definition of a scan line, the video signals P1, P2 are arranged interlacing with the video signals P1′, P2′, such as number 20 VOUT P1, P1′, P2, and P2′.

The design of staggered charge coupled devices is used vertical axle mapping. The horizontal axle mapping is used sampling method to raise the modulation transfer function (MTF) data. The vertical axle mapping is used micro-stepping and move expose continuously which cause modulation transfer function data of vertical axle too bad. The reason is shown to FIG. 3, a light-sensitive device 30 consists of charge-coupled devices, wherein the charge-coupled device comprises a photosensitive zones A and a non-photosensitive zones B. The light-sensitive device 30 caused the portion of photosensitive zones A image overlap at T=0 and T=1, T=1 and T=2 which reduced the argue color ratio and cause modulation transfer function data of vertical axle down. On the other hand, scanner of even/odd line must be one line distance of the linear staggered sensors array and increased a row line of memory and added the size of chip after process.

For the forgoing reasons, there is a necessity for an apparatus of linear stagger sensor for increasing modulation transfer function. This invention also reduced a row line of memory and shrunk the size of chip after process.

### SUMMARY OF THE INVENTION

It is an object of the present invention to provide an apparatus of linear staggered sensor. The shape of multiple sensor rows in the linear staggered sensor are moved the line distance of the linear staggered sensors array, reduced a row line of memory and shrunk the size of chip after process.

It is another object of the present invention to provide an apparatus of linear staggered sensor. The apparatus provides high modulation transfer function (MTF) of vertical axis of a scanned frame.

According to abovementioned objects, the present invention provides an apparatus of linear staggered sensor. The scanner comprises a first sensor and a second sensor. The first sensor is laterally offset from the second sensor, the sensors comprises a plurality of charge coupled devices, wherein the each of charge coupled device comprises a photosensitive zones and a non-photosensitive zones, the charge coupled devices of the sensors are linear arrangement; and the first sensor is abutting with the second sensor, wherein the first sensor is abutting place with the second sensor is the non-photosensitive zones.

### BRIEF DESCRIPTION OF THE DRAWINGS

A better understanding of the invention may be derived by reading the following detailed description with reference to the accompanying drawings wherein:

FIG. 1A shows the main structure of a charge-coupled device in a light-sensitive device in accordance with a prior art;

FIG. 1B is a plane view of the conventional square crystal structure in accordance with a prior art;

FIGS. 2A to 2B are schematic diagrams illustrating a video output of staggered sensor array in accordance with a prior art;

FIG. 3 is a plane view of the conventional linear staggered sensors apparatus in the continuous shift exposing process in accordance with a prior art;

FIG. 4A is a schematic diagram illustrating a first embodiment of charge-coupled device sensor in accordance with the present invention;

FIG. 4B is a plane view of the second embodiment of charge-coupled device sensor apparatus in the continuous shift expose in accordance with the present invention;

FIG. 5A is a schematic showing a staggered linear sensor photocell row with small line spacing in accordance with the present invention; and

FIG. 5B is a schematic showing a linear sensor devices exposing by a continuously movable exposing process in accordance with the present invention.

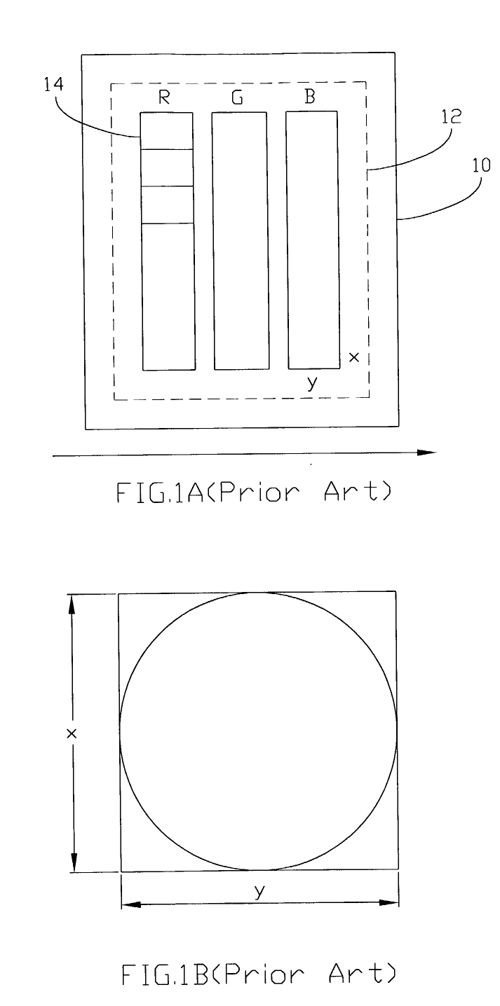

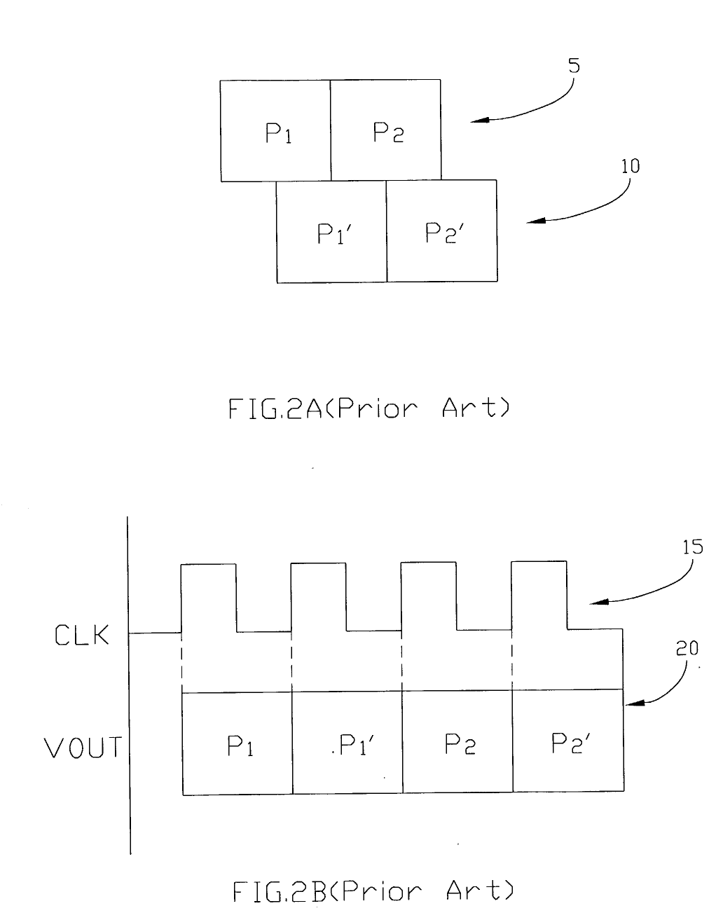

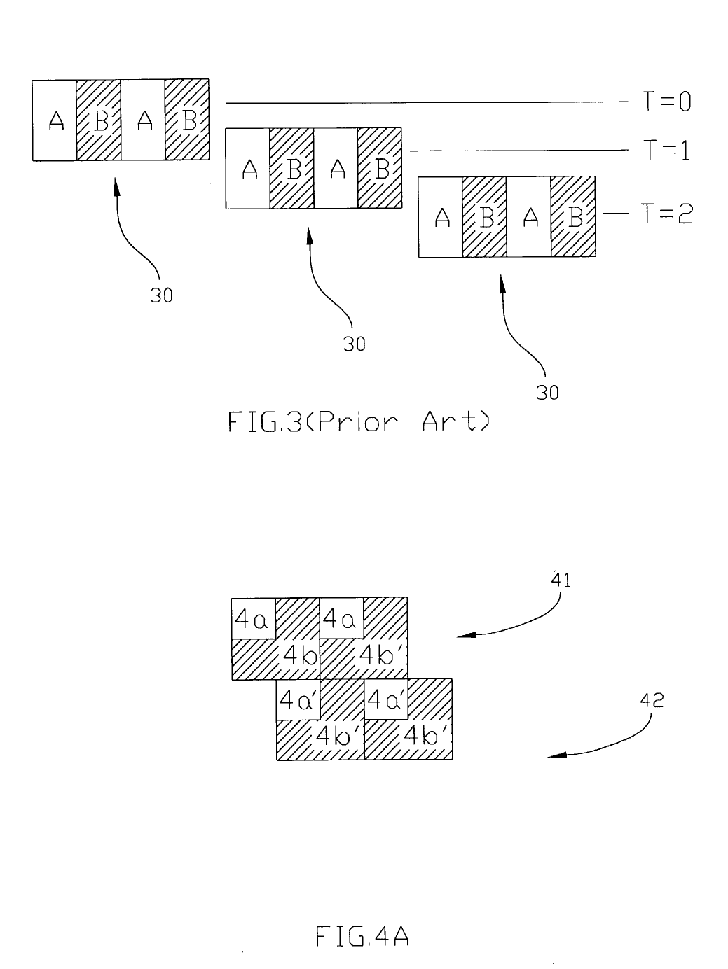

### DESCRIPTION OF THE PREFERRED EMBODIMENT

While the invention is described in terms of a single preferred embodiment, those skilled in the art will recognize that many devices described below can be altered as well as other substitutions with same function and can be freely made without departing from the spirit and scope of the invention.

Furthermore, there is shown a representative portion of video signals of the present, invention in enlarged. The drawings are not necessarily to scale for clarify of illustration and should not be interpreted in a limiting sense. Furthermore, the present invention can be applied on various image-capturing apparatuses, such as copier machine, MFP (Multiple-Function Product) or scanner.

In the present invention, an apparatus of linear staggered sensor. The scan comprises a first sensor and a second sensor. The first sensor is laterally offset from the second sensor, the sensors comprises a plurality of charge coupled devices, wherein the each of charge coupled device comprises a photosensitive zones and a non-photosensitive zones, the charge coupled devices of the sensors are linear arrangement; and the first sensor is abutting with the second sensor, wherein the first sensor is abutting place with the second sensor is the non-photosensitive zones.

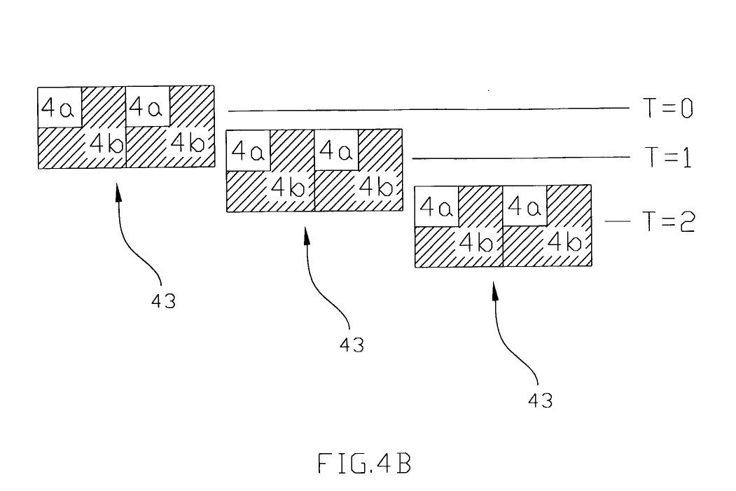

In a first embodiment of the present invention, a double staggered sensor array is used in a scanner. The double staggered sensor array can be a color sensor array. Thus, the double staggered sensor array comprises a first sensor row and a second sensor row wherein can consist of first row for detecting various color. The first sensor is offset abutting with the second sensor; wherein the first sensor is abutting place with the second sensor is the non-photosensitive zones. Shown in FIG. 4A, reference number 41 represents a first series of two photo photocells responded by the photocells in the first sensor row. Each charge-coupled devices consists of a photosensitive zones 4a and a non-photosensitive zones 4b, wherein the charge coupled devices of photocells is linear arrangement. The region of the photosensitive zones 4a is on the any region of non-photosensitive zones 4b. In the preferable embodiment of the present invention, the region of the photosensitive zones 4a is better located upper left on the region of non-photosensitive zones 4b. On the other hand, the photosensitive zones 4a area is smaller than the non-photosensitive zones 4b area. Wherein, the photosensitive zones 4a is smaller than a half of the non-photosensitive zones 4b. A feature of the photosensitive zones 4a can be a square-shaped or a polygon-shaped. In the preferable embodiment of the present invention, the feature of the photosensitive zones 4a is preferable to be a square-shaped. The reference number 42 represents two photocells responded by the photocells in the second sensor row. Each charge-coupled devices consists of a photosensitive zones 4a′ and a non-photosensitive zones 4b′, wherein the charge coupled devices of photocells is linear arrangement. The region of the photosensitive zones 4a′ is on the any region of non-photosensitive zones 4b′. In the preferable embodiment of the present invention, the region of the photosensitive zones 4a′ is better located upper left on the region of non-photosensitive zones 4b′, alternatively the region of the photosensitive zones 4a′ is better located upper right on the region of non-photosensitive zones 4b′. On the other hand, the area of photosensitive zones 4a′ is smaller than the are of non-photosensitive zones 4b′. The photosensitive zones 4a′ area is smaller than a half area of the non-photosensitive zones 4b′. A feature of the photosensitive zones 4a′ can be a square-shaped or polygon-shaped. In the preferable embodiment of the present invention, a feature of the photosensitive zones 4a′ is preferable to be a square-shaped. Furthermore, linear staggered sensor may be applied serially shift exposure method to read out the data samples from the photocells in successive rows of the double staggered sensor array.

Referring to FIG. 4B, a linear staggered charge coupled devices 43 does not image the overlap at T=0 and T=1, T=1 and T=2, when the linear staggered charge-coupled devices 43 serially shift exposure. The linear staggered charge-coupled devices 43 increase the argue color ratio and modulation transfer function data of vertical axle. On the other hand, the even/odd scanning line of the scanner without any line distance of the linear staggered sensors array and a row line of memory is reduced and the size of chip is shrunk after the post-process.

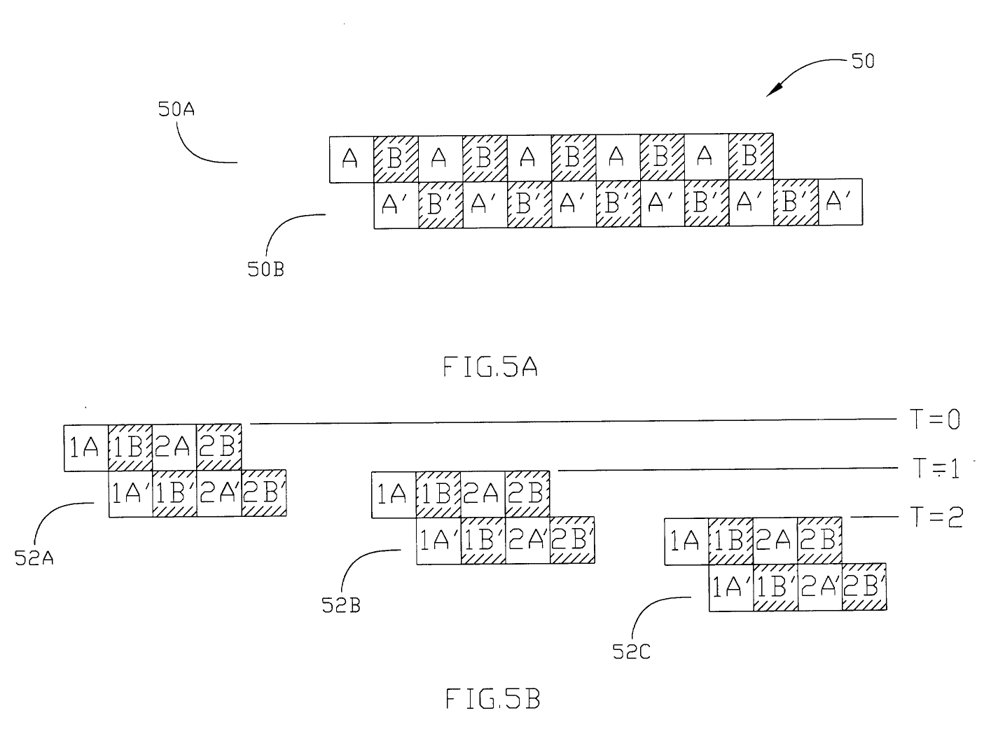

Referring to FIG. 5A, this is another embodiment of the present invention. In the FIG. 5A and FIG. 5B, the blank portion express a photosensitive zones A, A′, and the oblique lines portion express non-photosensitive zones B, B′. The FIG. 5A represents a improvement for the abovementioned embodiment when the horizontal axial mapping to raise modulation transfer function data, the charge-coupled devices squander in the direction of the vertical axial. The double staggered sensor array 50 is used in a scanner. The double staggered sensor array 50 can be a color sensor array. Thus, the double staggered sensor array 50 comprises a first sensor row 50A and a second sensor row 50B, wherein the double staggered sensor array 50 can consist of second sensor row 50B for detecting various color. The first sensor 50A is laterally offset from the second sensor 50B and between the line distances. Shown in FIG. 5A, reference number 50 represents two photo photocells responded by the photocells in the first sensor row 50A. Each charge-coupled device consists of photosensitive zones A and a non-photosensitive zones B; wherein the charge coupled devices of photocells is a linear arrangement. The region of the photosensitive zones A is on the sidewall of non-photosensitive zones B. A feature of the photosensitive zones A is a square-shaped or a polygon-shaped. In the second embodiment, a feature of the photosensitive zones A is preferable to be a square-shaped. Each charge-coupled devices consists of a photosensitive zones A′ and a non-photosensitive zones B′, wherein the charge-coupled devices of photocells represents a linear arrangement. The region of the photosensitive zones A′ is on sidewall of non-photosensitive zones A′. A feature of the photosensitive zones A′ can be a square-shaped or a polygon-shaped. In the alternative embodiment, referring to FIG. 5B, a feature of the photosensitive zones′ 1A, 1A′ are preferable to be a square-shaped. Furthermore, linear staggered sensor may be applied serially shift exposure method to read out the data samples from the photocells in successive rows of the double staggered sensor array.

In the FIG. 5B, a linear staggered charge coupled devices 52A, 52B, and 52C did not image overlap at T=0 and T=1, T=1 and T=2 when linear staggered charge coupled devices 52A, 52B, and 52C serially shift exposure. The linear staggered charge coupled devices 52A, 52B, and 52C increase the argue color ratio and modulation transfer function data of vertical axle. On the other hand, scanner of even/odd line without any line distance of the linear staggered sensors array and reduced a row line of memory and shrunk the size of chip after process.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A linear staggered sensor photocell rows structure, said linear sensor photocell rows structure comprising:
a first linear sensor photocell row and a second linear sensor photocell row, said second linear photocell row transverse offset said first linear sensor photocell row, and said first linear sensor photocell row and said second linear photocell row have a plurality of sensor device, respectively, wherein each said plurality of sensor device have a photosensitive zones and a non-photosensitive zones; and
an abutting area located on said non-photosensitive area of said first linear sensor photocell row and of said second linear sensor photocell row.

2. The linear staggered sensor photocell rows structure according to claim 1, wherein said plurality of sensor device comprises charge-coupled device.

3. The linear staggered sensor photocell rows structure according to claim 1, wherein shaped of said plurality of sensor device is selected from a group consisting of a square-shaped and a polygon-shaped.

4. The linear staggered sensor photocell rows structure according to claim 1, wherein said photosensitive zones is on the upper-right of said non-photosensitive zones.

5. The linear staggered sensor photocell rows structure according to claim 1, wherein said photosensitive area on the upper left said non-photosensitive zones.

6. The linear staggered sensor photocell rows structure according to claim 1, wherein the area of said photosensitive zones is smaller than said non-photosensitive zones.

7. The linear staggered sensor photocell rows structure according to claim 1, wherein the area of said photosensitive zones is at least half of said non-photosensitive zones.

8. The linear staggered sensor photocell rows structure according to claim 1, wherein exposing process comprises a mapping process in vertical direction.

9. The linear staggered sensor photocell rows structure according to claim 11, wherein said micro-stepping process comprises a continuously movable exposing process.

10. A linear sensor photocell rows structure, said linear sensor photocell rows comprising:
a first linear photocell row and a second linear photocell row, said first linear photocell row and said second linear photocell row have a plurality of sensor device, wherein each said plurality of sensor device have a photosensitive area and a non-photosensitive area; and
an abutting area located on said non-photosensitive area of said first linear photocell row and said second linear photocell row.

11. The linear sensor photocell rows structure according to claim 10, wherein said plurality of sensor device comprises charge-coupled device.

12. The linear staggered sensor photocell rows structure according to claim 10, wherein shaped of said plurality of sensor device is selected from a group consisting of a square-shapedand a polygon-shaped.

13. The linear sensor photocell rows structure according to claim 10, wherein exposing process comprises a mapping process in vertical direction.

14. The linear sensor photocell rows structure according to claim 10, wherein said micro-stepping process comprises a continuously movable exposing process.
